(19) United States
(12) Patent Application Publication
(10) Pub. No.: US 2022/0145457 A1
(43) Pub. Date: May 12, 2022

(54) VAPORIZING APPARATUS FOR THIN FILM DEPOSITION

(71) Applicant: M. I. Co., Ltd., Asan (KR)

(72) Inventor: Gi Nam KIM, Cheonan (KR)

(73) Assignee: M. I. Co., Ltd.

(21) Appl. No.: 17/103,987

(22) Filed: Nov. 25, 2020

(30) Foreign Application Priority Data
Nov. 11, 2020 (KR) 10-2020-0150095

(51) Int. Cl. C23C 16/448; B01B 1/00

(52) U.S. Cl. CPC C23C 16/4486; B01B 1/005

(57) ABSTRACT

A vaporizing apparatus for thin film deposition is provided. The vaporizing apparatus includes an atomizer configured to mix a source injected through a source inlet and a carrier gas injected through a carrier gas inlet and spray a mixed gas, a vaporizing unit including a first vaporization area and a second vaporization area, which are configured to vaporize the mixed gas sprayed from the atomizer, and configured to discharge a vaporized gas as a process gas through an outlet, and a heating unit configured to maintain the mixed gas in the vaporizing unit at a fixed temperature. The heating unit includes a first heating part arranged to surround the first vaporization area and configured to maintain the temperature of the mixed gas in the first vaporization area and a second heating part arranged to enclose the second vaporization area with the first heating part and configured to maintain the temperature of the mixed gas in the second vaporizing space.

### BACKGROUND OF THE INVENTION

### Field of the Invention

Various embodiments may generally relate to a vaporizing apparatus for thin film deposition, and more particularly to a vaporizing apparatus with high vaporization efficiency, which is used to deposit a thin film in semiconductor fabrication and is capable of preventing recondensation of sprayed droplets through an improved heater structure.

### Description of the Related Art

In general, semiconductor devices, display devices, and the like are manufactured through a series of processes such as a thin film deposition process and a photolithography process using a semiconductor manufacturing apparatus. Among the series of processes, the thin film deposition process for forming a thin film on a substrate may be performed through a chemical vapor deposition (CVD) method or an atomic layer deposition (ALD) method.

Typically, the thin film deposition process may be a process which forms a thin film on a substrate (wafer) by injecting a process gas into a process chamber to cause reaction on the substrate. The process gas is formed by vaporizing a liquid source and mixing the vaporized source and a carrier gas. To form the process gas, a vaporizing apparatus has to be provided in a semiconductor manufacturing apparatus.

A vaporizing apparatus used in the semiconductor fabrication process may be an apparatus which vaporizes a liquid source in the inside thereof and supplies the vaporized source to a process chamber, and has to supply the vaporized source to the process chamber while preventing the gaseous source from being cooled.

However, when the efficiency in vaporization of a liquid source into a gaseous source is low, a non-vaporized source may be adhered to an inner wall of a vaporizing apparatus or a filter, and thus the life span may be degraded and device failure may be caused.

To solve the problems, a method of vaporizing a liquid source in a decompression manner has been employed. However, the decompressing vaporization method may vaporize only a portion of the liquid source, and thus the deterioration in the valorization efficiency still exists. Accordingly, to vaporize the liquid source entirely or vaporize the liquid source over a desired amount, a configuration of a vaporizing apparatus is inevitably complicated or enlarged.

Due to the complication or enlargement of the vaporizing apparatus, the source vaporized in the vaporizing apparatus may be liquefied again while the vaporized source flows in a complicate passage in the vaporizing apparatus. Further, to vaporize a large amount of liquid source, the vaporizing apparatus may be more complicated and enlarged, and thus the above-described problems may be more aggravated, the design of the vaporizing apparatus is more complicated, and the manufacturing cost is increased.

### SUMMARY OF THE INVENTION

Embodiments are provided to a vaporizing apparatus for thin film deposition used in semiconductor fabrication and capable of improving a vaporization efficiency.

Embodiments are provided to a vaporizing apparatus for thin film deposition capable of improving a vaporization efficiency by preventing recondensation of sprayed droplets through improvement in a heater structure.

Embodiments are provided to a vaporizing apparatus for thin film deposition capable of improving a vaporization efficiency by allowing sprayed droplets to first collide with a heater installed in the inner side of a vaporizer body to be atomized and vaporizing the atomized droplets in a vaporization area.

Embodiments are provided to a vaporizing apparatus for thin film deposition capable of maximizing a vaporization efficiency by providing atomized droplets to a vaporization area through a vaporization passage between an inner heater and an outer heater.

In an embodiment of the present disclosure, a vaporizing apparatus may include: an atomizer configured to mix a source injected through a source inlet and a carrier gas injected through a carrier gas inlet and spray a mixed gas; a vaporizing unit including a first vaporization area and a second vaporization area, which are configured to vaporize the mixed gas sprayed from the atomizer, and configured to discharge a vaporized gas as a process gas through an outlet; and a heating unit configured to maintain the mixed gas in the vaporizing unit at a fixed temperature. The heating unit may include a first heating part arranged to surround the first vaporization area and configured to maintain the temperature of the mixed gas in the first vaporization area; and a second heating part arranged to enclose the second vaporization area with the first heating part and configured to maintain the temperature of the mixed gas in the second vaporization area.

The heating unit may further include a third heating part arranged in an outer side of a discharging pipe including the outlet and configured to maintain a temperature of the vaporized gas discharged through the outlet. The first heating part, the second heating part, and the third heating part may be configured of heaters having a heating wire form, and the second heating part and the third heating part may be integrally formed in a one heating wire.

The carrier gas inlet may have a reduction tube shape that a portion from which the carrier gas is discharged may have a narrower passage than a portion into which the carrier gas flows.

The carrier gas inlet may include a first portion into which the carrier gas flows; and a second portion which communicates with the vaporizing unit and is downwardly inclined toward the vaporizing unit with respect to the first portion. A passage of the second portion may be narrower than that of the first portion.

The vaporizing unit may include a first vaporizing part configured to communicate with the atomizer and including the first vaporization area configured to first vaporize the mixed gas sprayed from the atomizer; and a second vaporizing part including the second vaporization area and configured to completely vaporize the mixed gas flowing from the first vaporizing part and discharge the vaporized gas as the process gas.

The first vaporizing part may include a cylindrical container portion arranged to be spaced from the atomizer in the second vaporizing part and a plurality of bar-shaped fixing portions configured to fix the container portion. Space portions between the plurality of fixing portions may be configured to communicate with the second vaporizing part. The first heating part may be arranged on an outer side surface and an outer bottom surface of the container portion so that the first vaporization area is surrounded by the first heating part.

The second vaporizing part may be configured of a cylindrical outer tube, and the second heating part may be arranged on an outer side surface and an outer bottom surface of the outer tube so that the second vaporization area is configured to be enclosed by the first and second heating parts.

The vaporizing unit may further include a vaporization passage configured to communicate between the first vaporizing part and the second vaporizing part and guide the mixed gas from the space portions of the first vaporizing part to the second vaporizing part.

The vaporization passage may be arranged between a portion of the first heating part formed in the outer side surface of the container portion and a portion of the second heating part formed on the outer side surface of the outer tube so that the mixed gas passing through the vaporization passage may be heated by the first and second heating parts.

According to the present technology, the vaporizing apparatus may improve the structures of a vaporizing unit and a heating unit to vaporize and discharge a mixed gas with a fixed temperature.

The vaporizing apparatus may include heaters in the inside and outside of a vaporizer body to improve a vaporization efficiency and prevent recondensation of a mixed gas as compared with the related vaporizing apparatus including only a heater arranged in the outside of a vaporizer body.

Further, the vaporizing apparatus may install a heater even in a discharge pipe, which is configured to discharge a vaporized gas as a process gas, to discharge the vaporized gas to the outside, for example, a process chamber while maintaining uniform particles and uniform temperature in a state that a vaporization efficiency is maximized.

These and other features, aspects, and embodiments are described below.

### BRIEF DESCRIPTION OF THE DRAWING FIGURES

The above and other aspects, features and advantages of the subject matter of the present disclosure will be more clearly understood from the following detailed description taken in conjunction with the accompanying drawings, in which:

FIG. 1 is a perspective view illustrating a vaporizing apparatus for thin film deposition when viewed in a bottom according to an embodiment of the present disclosure;

FIG. 2 is a perspective view illustrating a vaporizing apparatus for thin film deposition when viewed in a top according to an embodiment of the present disclosure;

FIG. 3 is a diagram illustrating a cross-sectional structure of a vaporizing apparatus for thin film deposition according to an embodiment of the present disclosure;

FIG. 4 is a enlarged cross-sectional diagram illustrating a carrier gas inlet in a vaporizing apparatus for thin film deposition according to an embodiment of the present disclosure;

FIG. 5 is a detailed cross-sectional diagram illustrating a first heating part in a vaporizing apparatus for thin film deposition according to an embodiment of the present disclosure;

FIG. 6 is a diagram illustrating a vaporization path of a liquid source in a vaporizing apparatus for thin film deposition according to an embodiment of the present disclosure;

FIG. 7 is a diagram illustrating vaporization performance of a vaporizing apparatus for thin film deposition according to an embodiment of the present disclosure and a vaporizing apparatus in the related art;

FIG. 8A is a graph illustrating performance of a heating unit in a vaporizing apparatus including an external heater in the related art;

FIG. 8B is a graph illustrating performance of a heating unit in a vaporizing apparatus according to an embodiment of the present disclosure; and

FIG. 9 is a diagram illustrating a table showing uniformity of particle sizes and a residual amount of a source in the inside of a vaporizer body according to an embodiment of the present disclosure and in the related art.

### DETAILED DESCRIPTION OF THE EXEMPLARY EMBODIMENTS

Hereinafter, exemplary embodiments of the disclosure will be described more fully with reference to the accompanying drawings, in which the exemplary embodiments of the disclosure are shown to understand a configuration and an effect of the disclosure. However, specific structural and functional details disclosed herein are merely representative for purposes of describing exemplary embodiments. Thus, the invention may be embodied in many alternate forms and should not be construed as limited to only exemplary embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the inventive concept.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that the terms first, second, third, etc. may be used herein to describe various elements and/or components regardless of the order and/or importance, and these elements and/or components should not be limited by these terms. These terms are only used to distinguish one element or component. Thus, without departing from the scope in the document, a first element and/or component discussed below could be termed a second element and/or component, and vice versa.

Spatially relative terms, such as “beneath,” “below,” “lower,” “above,” “upper” and the like, may be used herein for ease of description to describe one element or a relationship between a feature and another element or feature as illustrated in the figures. For example, if the apparatus in the figures is turned over, elements described as “below” or “beneath” other elements or features would then be oriented “above” the other elements or features.

In the drawings, the thicknesses and volumes of layers and regions may be exaggerated for clarity, and like numbers refer to like elements throughout the description of the figure.

Hereinafter, a vaporizing apparatus for thin film deposition according to an embodiment of the present disclosure will be described with reference to the accompany drawings in detail.

A vaporizing apparatus 1000 for thin film deposition according to an embodiment may be a vaporizing apparatus which is used for a deposition process for depositing a thin film on a substrate (wafer) during a fabrication process of a semiconductor device or a display device such as a liquid crystal display (LCD) or a light emitting diode (LED), and mixes and vaporizes a liquid source and a carrier gas and discharges a vaporized gas as a process gas to a process chamber configured to deposit a semiconductor thin film through an outlet. The source may contain a raw material of the thin film to be formed on the substrate, and a carrier gas may be gas for carrying the source without reaction with the source and include, for example, N₂ gas and the like.

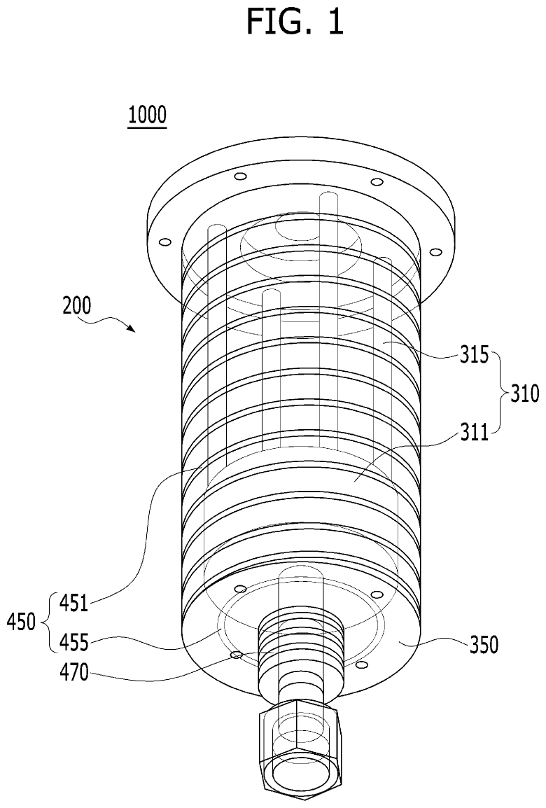

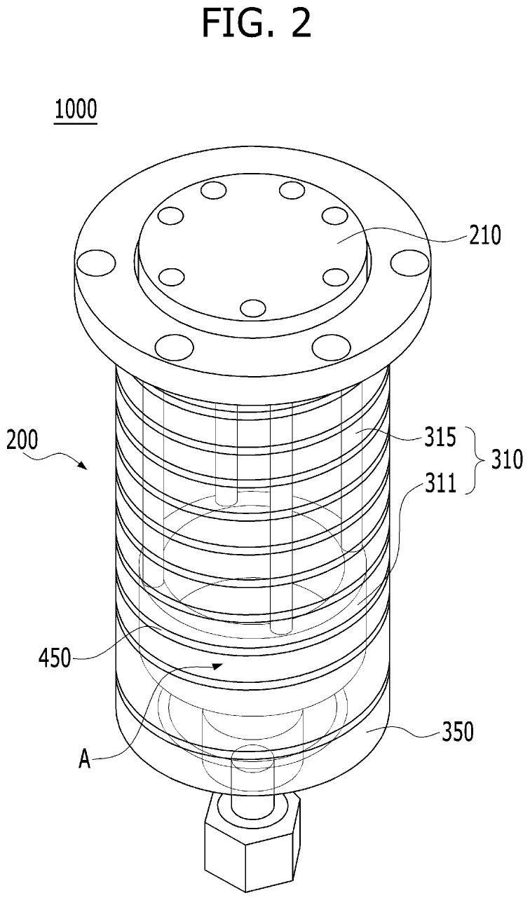

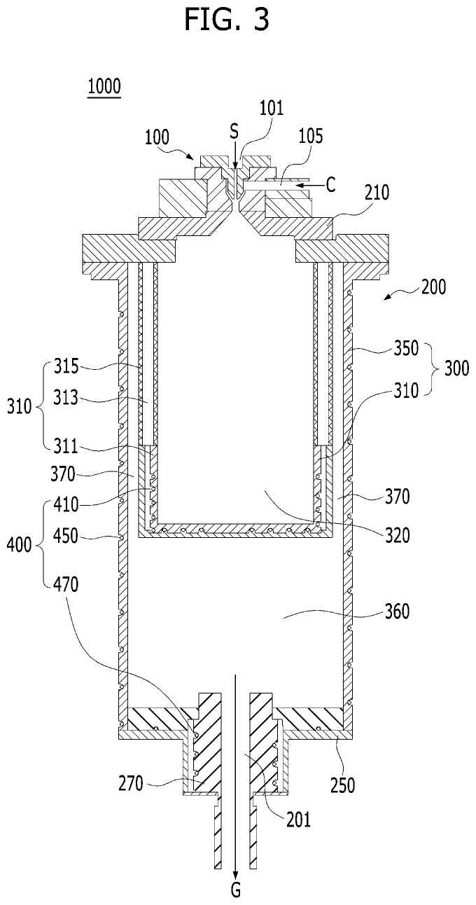

FIG. 1 is a perspective view illustrating the vaporizing apparatus 1000 for thin film deposition when viewed from the bottom according to an embodiment of the present disclosure and FIG. 2 is a perspective view illustrating the vaporizing apparatus 1000 for thin film deposition when viewed from the top according to an embodiment of the present disclosure. Only a vaporizer body 200 is illustrated in FIGS. 1 and 2. FIG. 3 is a cross-sectional diagram illustrating the vaporizing apparatus 1000 for thin film deposition according to an embodiment of the present disclosure. For understanding of the present disclosure, all four fixing portions 315 and space portions 313 for moving the mixed gas between the fixing portions 315 are illustrated in the cross-sectional structure of FIG. 3.

Referring to FIGS. 1 to 3, the vaporizing apparatus 1000 according to an embodiment may be configured to stably vaporize fine droplets sprayed from an atomizer 100 and supply a vaporized gas as a process gas to a process chamber (not shown) through an outlet 201, and may be largely divided into the atomizer 100 and the vaporizer body 200.

The atomizer 100 may be configured to mix a liquid source S and a carrier gas C to spray fine droplets. The atomizer 100 may include a source inlet 101 into which the liquid source S is injected and a carrier gas inlet 105 into which the carrier gas C is injected. For example, the atomizer 100 may mix the liquid source S supplied from the outside through the source inlet 101 and the carrier gas C supplied from the outside through the carrier gas inlet 105 and spray a mixed gas (fine droplets) into the vaporizer body 200.

The source inlet 101 may be a path that the liquid source S supplied from a source supply unit (not shown) as a vaporization target flows into the vaporizing apparatus 1000, for example, the atomizer 100, and the carrier gas inlet 105 may be a path that the carrier gas C supplied from a carrier gas supply unit (not shown) flows into the atomizer 100.

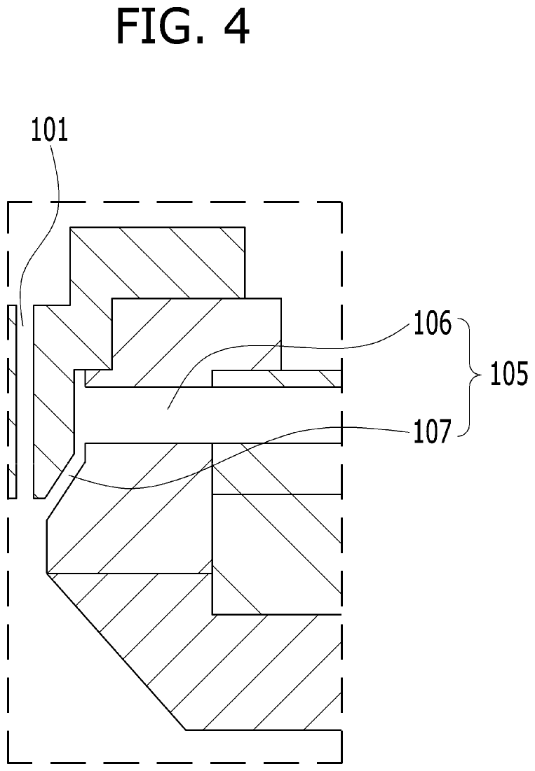

Specifically, referring to FIG. 4, the carrier gas inlet 105 may have a tubular shape and include a first portion 106 and a second portion 107. The first portion 106 may be a portion into which the carrier gas C is injected from the carrier gas supply unit, and the second portion 107 may be a portion which communicates with the vaporizing unit 300 and allow the carrier gas C to be supplied to the vaporizing unit 300. The second portion 107 may have an inclined structure with respect to the first portion 106. For example, the second portion 107 may have a downwardly inclined structure toward the vaporizing unit 300 with respect to the first portion 106.

The carrier gas inlet 105 may have a reduction tube shape that a passage of the second portion 107 is formed to be narrower than that of the first portion 106 so that the carrier gas C injected through the first portion 106 is guided to the vaporizing unit 300 along an inclined surface of the second portion 107. Due to the reduction tube shape of the carrier gas inlet 105, when the carrier gas C is mixed with the liquid source S and sprayed, finer droplets may be sprayed by pressure.

The vaporizer body 200 may include a housing (not shown) in which the vaporizing unit 300 to be described later is accommodated, an upper cap 210 coupled to the atomizer 100 and configured to cover an upper end of the housing, and a lower cap 250 coupled to the discharge pipe 270 and configured to cover a lower end of the hosing.

The vaporizing apparatus 1000 may include the vaporizing unit 300 provided in the vaporizer body 200 and configured to vaporize the mixed gas sprayed from the atomizer 100. The vaporizing unit 300 may include a first vaporizing part 310 configured to first vaporize the mixed gas sprayed from the atomizer 100 and a second vaporizing part 350 configured to completely vaporize the mixed gas vaporized in the first vaporizing part 310.

The first vaporizing part 310 may be configured to allow the mixed gas (droplets) sprayed from the atomizer 100 to collide to be finer. An upper side of the first vaporizing part 310 may be configured to communicate with the atomizer 100. The first vaporizing part 310 may include a cylindrical container portion 311 disposed to be spaced from the atomizer 100 and serving as a first vaporization area 320 and a plurality of bar-shaped fixing portions 315 fixed to the upper cap 210 and configured to fix the container portion 311. In an embodiment, it has been illustrated that the plurality of fixing units 315 include four bars, but this is not limited thereto.

The space portion 313, which is between the fixing portions 315 of the first vaporizing part 310 and allows the mixed gas to be moved, may serve as a path through which the mixed gas vaporized in the first vaporizing part 310 moves to the second vaporizing part 350. It has been illustrated that the container portion 311 has a cylindrical structure, but this is not limited thereto. It has been illustrated that the container portion 311 is fixed to the upper cap 210 through the bar-shaped fixing portions 315, but this is not limited thereto and the fixing portions 315 may have any structure which provides a path (for example, space portion 313) through which the mixed gas vaporized in the container portion 311 flows into the second vaporizing part 350.

The mixed gas sprayed from the atomizer 100 to the first vaporizing part 310 may not be completely vaporized in the first vaporizing part 310 but may be partially vaporized in the first vaporizing part 310 and a portion of the mixed gas may remain in a liquid state. The second vaporizing part 350 may be configured to vaporize the mixed gas flowing from the first vaporizing part 310 completely. The second vaporizing part 350 may be configured of a cylindrical outer tube and include a second vaporization space 360 in the inside of the outer tube. An inner diameter of the outer tube of the second vaporizing part 350 may be configured to be larger than an outer diameter of the container portion 311 of the first vaporizing part 310.

The vaporizing unit 300 may further include a vaporization passage 370 which communicates between the first vaporizing part 310 and the second vaporizing part 350 and is configured to guide the vaporized mixed gas from the first vaporizing part 310 to the second vaporizing part 350. The vaporization passage 370 may be configured of a space which communicates with the space portion 313 of the first vaporizing part 310 and is spaced between the outer diameter of the container portion 311 of the first vaporizing part 310 and the inner diameter of the second vaporizing part 350.

The vaporizing apparatus 1000 according to an embodiment may further include the discharge pipe 270 provided in the vaporizer body 200 and including the outlet 201 configured to discharge a vaporized gas G from the vaporizing unit 300 as a process gas. Although not shown in drawings, the vaporized gas G discharged through the outlet 201 may be introduced into a process chamber for thin film deposition as the process gas.

The vaporizing apparatus 1000 according to an embodiment may further include a heating unit 400 provided in the vaporizer body 200. The heating unit 400 may include a first heating part 410 disposed in the vaporizer body 200, for example, in the inner side of the vaporizing unit 300 and a second heating part 450 disposed in the vaporizer body 200, for example, in the outer side of the vaporizing unit 300.

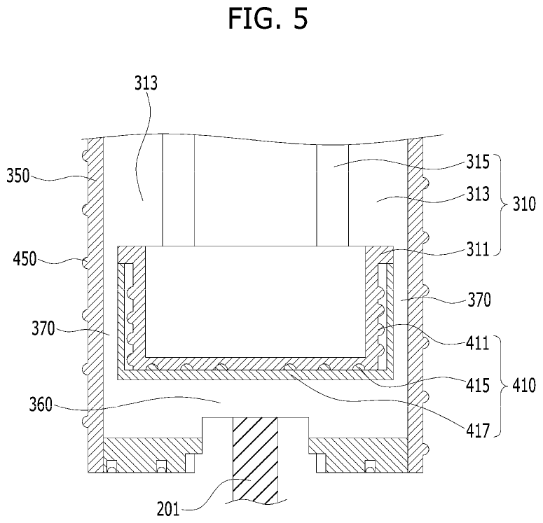

FIG. 5 is a detailed cross-sectional diagram illustrating the first heating part 410 in the vaporizing apparatus 1000 according to an embodiment.

Referring to FIG. 5, the first heating part 410 may be disposed corresponding to the first vaporizing part 310. Specifically, the first heating part 410 may be arranged in the outer side of the container portion 311 of the first vaporizing part 310 and may be divided into a first portion 411 formed along an outer side surface of the container portion 311 and a second portion 415 formed in an outer bottom surface of the container portion 311.

The first portion 411 and the second portion 415 of the first heating part 410 may include heaters having a heating wire form and may be integrally formed, but this is not limited thereto and the first heating part 410 may be implemented in various forms. The first portion 411 and the second portion 415 of the first heating part 410 may be covered with a protection cap 417. The protection cap 417 may be attached to the container portion 311 of the first vaporizing part 310 through welding.

The second heating part 450 may be disposed corresponding to the second vaporizing part 350. For example, the second heating part 450 may be arranged in the outer tube of the second vaporizing part 350 and may be divided into a first portion 451 formed along the outer side surface of the outer tube 350 and a second portion 455 formed in an outer bottom surface of the outer tube 350. The first portion 451 and the second portion 455 of the second heating part 450 may include heaters having a heating wire form and may be integrally formed, but this is not limited thereto and may be implemented in various forms.

The first heating part 410 may be formed to surround the first vaporization area 320 in the outer bottom surface and the outer side surface of the container portion 311 of the first vaporizing part 310 so that the mixed gas sprayed from the atomizer 100 may collide, and thus the vaporization efficiency of the mixed gas in the first vaporization area 320 may be maximized and recondensation of the mixed gas may be prevented.

The second heating part 450 may be formed to surround the second vaporization area 360 in the outer side surface and the outer bottom surface of the second vaporizing part 350 so that the mixed gas in the second vaporization area 360 may be completed vaporized.

Further, the first heating part 410 may be arranged in an upper side of the second vaporization area 360, and the second vaporization area 360 may be formed to be substantially enclosed by the first heating part 410 and the second heating part 450. Accordingly, the heat loss in the second vaporization area 360 may be prevented and the temperature of the mixed gas may be uniformly maintained, and thus the vaporization efficiency in the second vaporization area 360 may be further improved.

Further, the vaporization passage 370 formed between the first vaporizing part 310 arranged with the first heating part 410 and the second vaporizing part 350 arranged with the second heating part 450 may be arranged between the first heating part 410 and the second heating part 450, and thus the mixed gas supplied from the first vaporizing part 310 through the vaporization passage 370 may be supplied to the second vaporizing part 350 with a constant temperature.

The heating unit 400 may further include a third heating part 470 arranged corresponding to the discharge pipe 270. The third heating part 470 may allow the gas G vaporized in the second vaporization area 360 to be provided to the process chamber for thin film deposition while the temperature of the gas G as the process gas is uniformly maintained.

The third heating part 470 may be a heater having a heating wire form. The third heating part 470 may be integrally formed with the second heating part 450 in one heating wire, but this is not limited thereto and may be implemented in various forms.

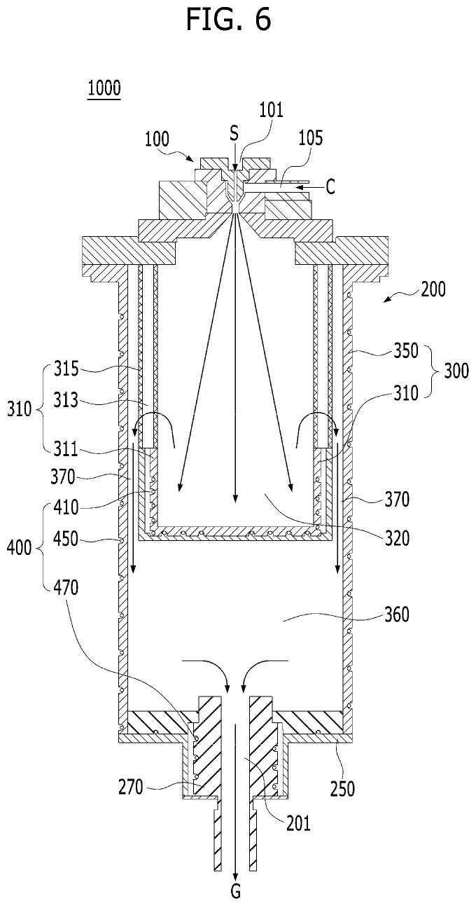

FIG. 6 is a diagram explaining a vaporization process of the vaporizing apparatus 1000 for thin film deposition according to an embodiment.

Referring to FIG. 6, when the liquid source S is introduced through the source inlet 101 and the carrier gas C is introduced through the carrier gas inlet 105, the atomizer 100 may mix the source S and the carrier gas C and spray the mixed gas, for example, fine droplets to the vaporizing unit 300. The mixed gas sprayed from the atomizer 100 may be partially vaporized and a portion of the mixed gas may be maintained in a liquid state.

At this time, due to the reduction tube structure of the atomizer 100, the carrier gas C may be guided along the inclined surface of the carrier gas inlet 105 so that the finer droplets may be sprayed due to pressure when the liquid source S and the carrier gas C are mixed.

The mixed gas sprayed from the atomizer 100 may be introduced into the first vaporizing part 310 of the vaporizing unit 300 and then vaporized in the first vaporizing part 310. The mixed gas introduced into the first vaporizing part 310 may be heated and collide in the container portion 311 of the first vaporizing part 310 by the first heating part 410 to be finer. The mixed gas in the first vaporizing part 310 may collide with each other to be in a gaseous state and the mixed gas may be introduced into the second vaporizing part 350 through the space portion 313 via the vaporization passage 370. At this time, the first vaporization area 320 of the first vaporizing part 310 may be surrounded by the first heating part 410 and the mixed gas may be heated by the first heating part 410, so that the vaporization efficiency in the first vaporization area 320 may be maximized and the condensation of the mixed gas may be prevented.

Since the mixed gas introduced into the second vaporizing part 350 may be introduced via the vaporization passage 370 arranged between the first heating part 410 and the second heating part 450, the mixed gas may be introduced into the second vaporization area 360 of the second vaporizing part 350 while the temperature of the mixed gas is uniformly maintained by the first and second heating parts 410 and 450.

The second vaporization area 360 may be enclosed by the first heating part 410 and the second heating part 450, and thus the heat loss may be prevented and the temperature of the mixed gas may be uniformly maintained. Accordingly, the vaporization efficiency of the mixed gas in the second vaporizing part 350 may be maximized and the recondensation of the mixed gas may be prevented.

The mixed gas may be completely vaporized in the second vaporizing part 350, and the vaporized gas G may be supplied to the outside, for example, a process chamber as a process gas through the outlet 201.

The vaporizing apparatus according to an embodiment may include the heaters disposed in both the inner side and outer side of the vaporizer body. Accordingly, the vaporizing apparatus according to an embodiment may solve the problem that the vaporization efficiency is deteriorated due to the low inner temperature of the vaporizer body in the related vaporizing apparatus including only a heater in the outer side of the vaporizer body. Further, the generation of particles due to recondensation of droplets sprayed from the atomizer in the inside of the vaporizer body may be prevented, and thus the adhesion of the particles to a filter, a vaporizer, and the like may be prevented.

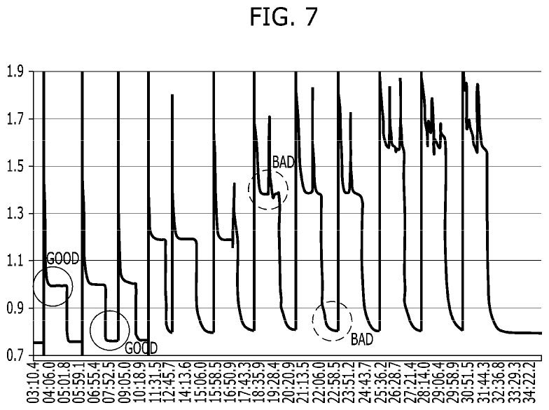

FIG. 7 is a diagram illustrating a rate of rise (ROR) test result in the vaporizing apparatus according to an embodiment and the vaporizing apparatus in the related art.

The ROR test may refer to a ratio of a pressure increase time to a time that a vacuum system is abruptly separated from a pump using a valve under the condition that the volume and temperature of the vacuum system are constantly maintained during measurement of the increase ratio in the leakage experiment.

Since the deposition process using the vaporizing apparatus is performed in a vacuum state, it is impossible to visually confirm the vaporization process in the vaporizing apparatus and the vaporization performance, and thus the vaporization performance index may be indirectly obtained through change in the vacuum degree of a pipe after the vaporization process.

As compared with the related vaporizing apparatus (a portion indicated by an upper dotted line), it can be seen from FIG. 7 that during the process, the degree of vacuum is not largely swing and uniformity of particles is good when linearity is maintained, in the vaporizing apparatus according to an embodiment (a portion indicated by an upper solid line).

As compared with the related vaporizing apparatus (a portion indicated by a lower dotted line), it can be seen that after the process is performed, the degree of vacuum immediately returns to the base vacuum degree in the vaporizing apparatus according to an embodiment (a portion indicated by a lower solid line). This is, it can be seen that the mixed gas does not remain in the vaporization area and the injected source is immediately vaporized after the process due to the excellent vaporization performance in the vaporizing apparatus according to an embodiment. Further, the degree of vacuum does not immediately return to the base vacuum degree after the process and slowly returns to the base vacuum degree, and thus tail is caused in the related vaporizing apparatus.

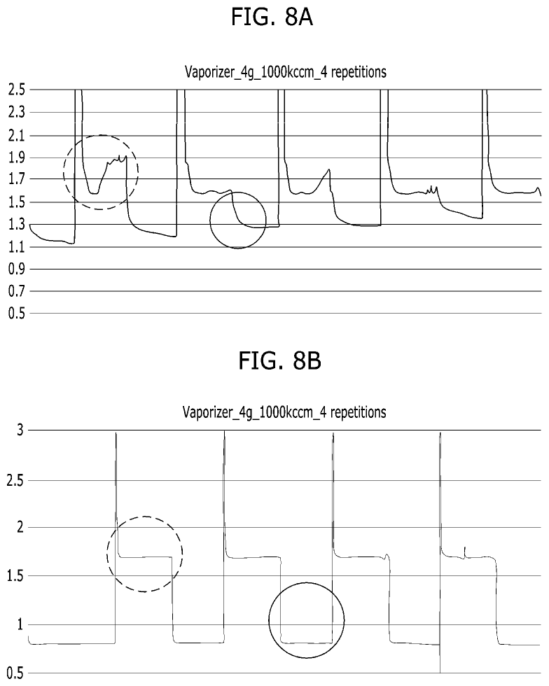

FIG. 8A illustrates the vaporization performance in the related vaporizing apparatus. It can be seen from FIG. 8A that due to the structure of the related vaporizing apparatus, for example, the structures of the heater and the atomizer in the related art, the uniformity of particle sizes (indicated by a dotted line) is not good and tail (indicated by a solid line) is caused.

FIG. 8B illustrates the vaporization performance in the vaporizing apparatus according to an embodiment. It can be seen from FIG. 8B that through structure improvement in the heating unit and the carrier gas inlet in the vaporizing apparatus according to an embodiment, the uniformity of particle sizes (indicated by a dotted line) during the process is good and tail (indicated by a solid line) is not caused. Accordingly, the recondensation of droplets may be prevented and adhesion of the non-vaporized source to the inner wall of the apparatus may be prevented.

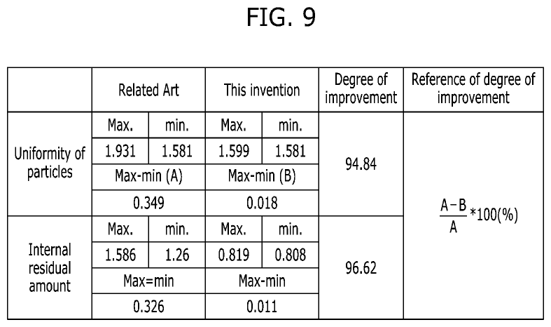

FIG. 9 illustrates the uniformity of particle sizes and the internal residual amount of a source in the vaporizing apparatus according to an embodiment and the related vaporizing apparatus.

As compared with the related vaporizing apparatus, it can be seen from FIG. 9 that the uniformity of particle sizes and the internal residual amount of the source are improved in the vaporizing apparatus according to an embodiment.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A vaporizing apparatus for thin film deposition comprising:
an atomizer configured to mix a source injected through a source inlet and a carrier gas injected through a carrier gas inlet and spray a mixed gas;
a vaporizing unit including a first vaporization area and a second vaporization area, which are configured to vaporize the mixed gas sprayed from the atomizer, and configured to discharge a vaporized gas as a process gas through an outlet; and
a heating unit configured to maintain the mixed gas in the vaporizing unit at a fixed temperature,
wherein the heating unit includes
a first heating part arranged to surround the first vaporization area and configured to maintain the temperature of the mixed gas in the first vaporization area; and
a second heating part arranged to enclose the second vaporization area with the first heating part and configured to maintain the temperature of the mixed gas in the second vaporization area.

2. The vaporizing apparatus for thin film deposition as claimed in claim 1, wherein the heating unit further includes a third heating part arranged in an outer side of a discharging pipe including the outlet and configured to maintain a temperature of the vaporized gas discharged through the outlet.

3. The vaporizing apparatus for thin film deposition as claimed in claim 2, wherein the first heating part, the second heating part, and the third heating part are configured of heaters having a heating wire form, and the second heating part and the third heating part are integrally formed in a one heating wire.

4. The vaporizing apparatus for thin film deposition as claimed in claim 1, wherein the carrier gas inlet has a reduction tube shape that a portion from which the carrier gas is discharged has a narrower passage than a portion into which the carrier gas flows.

5. The vaporizing apparatus for thin film deposition as claimed in claim 4, wherein the carrier gas inlet includes:
a first portion into which the carrier gas flows; and
a second portion which communicates with the vaporizing unit and is downwardly inclined toward the vaporizing unit with respect to the first portion,
wherein a passage of the second portion is narrower than that of the first portion.

6. The vaporizing apparatus for thin film deposition as claimed in claim 1, wherein the vaporizing unit includes:
a first vaporizing part configured to communicate with the atomizer and including the first vaporization area configured to first vaporize the mixed gas sprayed from the atomizer; and
a second vaporizing part including the second vaporization area and configured to completely vaporize the mixed gas flowing from the first vaporizing part and discharge the vaporized gas as the process gas.

7. The vaporizing apparatus for thin film deposition as claimed in claim 6, wherein the first vaporizing part includes a cylindrical container portion arranged to be spaced from the atomizer in the second vaporizing part and a plurality of bar-shaped fixing portions configured to fix the container portion, and space portions between the plurality of fixing portions are configured to communicate with the second vaporizing part, and
the first heating part is arranged on an outer side surface and an outer bottom surface of the container portion so that the first vaporization area is surrounded by the first heating part.

8. The vaporizing apparatus for thin film deposition as claimed in claim 7, wherein the second vaporizing part is configured of a cylindrical outer tube, and the second heating part is arranged on an outer side surface and an outer bottom surface of the outer tube so that the second vaporization area is configured to be enclosed by the first and second heating parts.

9. The vaporizing apparatus for thin film deposition as claimed in claim 8, wherein the vaporizing unit further includes a vaporization passage configured to communicate between the first vaporizing part and the second vaporizing part and guide the mixed gas from the space portions of the first vaporizing part to the second vaporizing part.

10. The vaporizing apparatus for thin film deposition as claimed in claim 9, wherein the vaporization passage is arranged between a portion of the first heating part formed in the outer side surface of the container portion and a portion of the second heating part formed on the outer side surface of the outer tube so that the mixed gas passing through the vaporization passage is heated by the first and second heating parts.
